(19) United States
(12) Patent Application Publication
(10) Pub. No.: US 2025/0048738 A1
(43) Pub. Date: Feb. 6, 2025

(54) THIN FILM TRANSISTOR AND DISPLAY APPARATUS COMPRISING THE SAME

(71) Applicant: LG Display Co., Ltd., Seoul (KR)

(72) Inventors: Dohyun KWAK, Paju-si (KR); Dohyung LEE, Paju-si (KR); HongRak CHOI, Paju-si (KR); GaWon YANG, Paju-si (KR)

(21) Appl. No.: 18/783,354

(22) Filed: Jul. 24, 2024

(30) Foreign Application Priority Data
Aug. 3, 2023 (KR) 10-2023-0101362

(51) Int. Cl. H01L 27/12

(52) U.S. Cl. CPC H01L 27/1225; H01L 27/124

(57) ABSTRACT

A thin film transistor and a display apparatus including the same are provided. The thin film transistor includes an active layer, a sub-conductive material layer on the active layer, a gate electrode spaced apart from the active layer and at least partially overlapping the active layer, and a conductive material layer on the active layer. The active layer includes a channel portion partially overlapping the gate electrode, a first connection portion connected to one side of the channel portion, and a second connection portion connected to the other side of the channel portion. The sub-conductive material layer includes a source conductive material layer on the first connection portion, and a drain conductive material layer on the second connection portion. The conductive material layer is disposed on the channel portion and is disposed on the same layer as the sub-conductive material layer.

### CROSS-REFERENCE TO RELATED APPLICATIONS

This application claims the benefit of priority of the Korean Patent Application No. 10-2023-0101362 filed on Aug. 3, 2023, which is hereby incorporated by reference as if fully set forth herein.

### BACKGROUND

### Technical Field

The present disclosure relates to a transistor and a display apparatus including the transistor.

### Description of the Related Art

Transistors are widely used as switching devices or driving devices in the field of electronic devices. In particular, since a thin film transistor may be manufactured on a glass substrate or a plastic substrate, it is widely used as a switching device of a display apparatus such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

The amorphous silicon thin film transistor (a-Si TFT) has the advantage of short manufacturing process time and low production cost because amorphous silicon can be deposited in a short time to form an active layer, but has the disadvantage of being limited in use in active matrix organic light emitting devices (AMOLEDs) because of low mobility and poor current driving ability and a change in threshold voltage.

Polycrystalline silicon thin film transistor (poly-Si TFT) is made by crystallizing amorphous silicon after amorphous silicon is deposited. Since a process of crystallizing amorphous silicon is required in the manufacturing process of a polycrystalline silicon thin film transistor, the manufacturing cost increases as the number of processes increases, and since the crystallization process is performed at a high process temperature, it is difficult to apply the polycrystalline silicon thin film transistor to a large area device. In addition, due to its polycrystalline properties, it is difficult to secure the uniformity of the polycrystalline silicon thin film transistor.

In an oxide semiconductor thin film transistor (TFT), since the oxide constituting the active layer can be formed at a relatively low temperature, has high mobility, and has a large resistance change according to the oxygen content, desired physical properties can be easily obtained. Also, due to the nature of the oxide, since the oxide semiconductor is transparent, it is also advantageous to implement a transparent display.

### BRIEF SUMMARY

In an oxide semiconductor thin film transistor (Oxide semiconductor TFT), if the active layer uses a high mobility material to improve the current characteristics of the transistor, problems may occur in the reliability of the transistor, and when a short channel is implemented, the threshold voltage Vth of the transistor is shifted to negative (−). Therefore, the inventors of the present disclosure have appreciated this technical problem in the related art and suggested methods for improving the current characteristics without the reliability of the transistor and the negative (−) shift issue of the threshold voltage Vth. Various embodiments of the present disclosure address the technical problems in the related art including the above-identified problem.

An embodiment of the present disclosure is to provide a thin film transistor having improved current characteristics by including a conductive material layer disposed on a channel portion.

An embodiment of the present disclosure is to provide a thin film transistor having improved current characteristics without excessively shifting a threshold voltage Vth in a negative (−) direction by including a conductive material layer disposed on a channel portion.

An embodiment of the present disclosure is to provide a thin film transistor which comprises a conductive material layer disposed on a channel portion, and maintains current characteristics even when the channel portion has a small width.

Another embodiment of the present disclosure is to provide a display apparatus including such a thin film transistor.

In addition to the technical benefits of the present disclosure as mentioned above, additional benefits and features of the present disclosure will be clearly understood by those skilled in the art from the following description of the present disclosure.

In accordance with an aspect of the present disclosure, the above and other objects can be accomplished by the provision of a thin film transistor including an active layer on a base substrate; a sub-conductive material layer on the active layer; a gate electrode spaced apart from the active layer and at least partially overlapping the active layer; and a conductive material layer on the active layer. The active layer includes a channel portion partially overlapping the gate electrode; a first connection portion connected to one side of the channel portion; and a second connection portion connected to the other side of the channel portion; The sub-conductive material layer includes a source conductive material layer on the first connection portion; and a drain conductive material layer on the second connection portion; The conductive material layer is disposed on the channel portion and is disposed on the same layer as the sub-conductive material layer.

In a plan view, an area of the conductive material layer in the channel portion may be 5 to 40% based on the total area of the channel portion.

Each of the source conductive material layer and the drain conductive material layer may overlap portions of the first connection portion and the second connection portion.

Each of the source conductive material layer and the drain conductive material layer may be disposed on the entire surfaces of the first connection portion and the second connection portion.

The conductive material layer may include a first conductive material layer and a second conductive material layer spaced apart from each other.

The first conductive material layer may be disposed closer to the first connection portion than the second conductive material layer.

The first conductive material layer and the second conductive material layer may be disposed on an arbitrary shortest line connecting the first connection portion and the second connection portion in a plan view.

The first conductive material layer and the second conductive material layer may not be disposed on an arbitrary shortest line connecting the first connection portion and the second connection portion in a plan view.

The first conductive material layer may include a first sub-conductive material layer and a second sub-conductive material layer spaced apart from each other, and the second conductive material layer may include a first sub-conductive material layer and a second sub-conductive material layer spaced apart from each other.

The conductive material layer may include a third conductive material layer disposed on the same distance as each of the first connection portion and the second connection portion in a plan view.

When the channel length direction of the active layer is a first direction and the width direction of the active layer is a second direction, the conductive material layer may include a fourth conductive material layer having a length in the second direction longer than a length in the first direction.

Based on the second direction, both ends of the fourth conductive material layer may contact both ends of the channel portion.

When the channel length direction of the active layer is a first direction and the width direction of the active layer is a second direction, the conductive material layer may include a fifth conductive material layer having a length in the first direction longer than a length in the second direction.

The fifth conductive material layer may be disposed in the channel portion based on the first direction.

Each distance between the fifth conductive material layer and the first connection portion and the second connection portion may be 1 μm or more based on the first direction.

A region of the channel portion overlapping the conductive material layer may have a higher carrier concentration than a region not overlapping the conductive material layer.

The sub-conductive material layer may include at least one selected from metal and transparent conductive oxide (TCO).

The conductive material layer may be formed of the same material as the sub-conductive material layer.

The active layer may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FelnZnO)-based oxide semiconductor material.

Another configuration of the present disclosure provides a display apparatus including the thin film transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor according to another embodiment of the present disclosure.

FIG. 5 is a cross-sectional view taken along line I-I′ of FIG. 4.

FIG. 6 is a cross-sectional view taken along line II-II′ of FIG. 4.

FIG. 7 is a cross-sectional view of a thin film transistor according to another embodiment of the present disclosure.

FIG. 8 is a cross-sectional view of a thin film transistor according to another embodiment of the present disclosure.

FIG. 9 is a plan view of a thin film transistor according to another embodiment of the present disclosure.

FIG. 10 is a plan view of a thin film transistor according to another embodiment of the present disclosure.

FIG. 11 is a plan view of a thin film transistor according to another embodiment of the present disclosure.

FIG. 12 is a plan view of a thin film transistor according to another embodiment of the present disclosure.

FIG. 13 is a plan view of a thin film transistor according to another embodiment of the present disclosure.

FIG. 14 is a plan view of a thin film transistor according to another embodiment of the present disclosure.

FIG. 15 is a plan view of a thin film transistor according to another embodiment of the present disclosure.

FIG. 16 is a plan view of a thin film transistor according to another embodiment of the present disclosure.

FIG. 17 is a plan view of a thin film transistor according to another embodiment of the present disclosure.

FIG. 18 is a plan view of a thin film transistor according to another embodiment of the present disclosure.

FIGS. 19A and 19B are plan views of thin film transistors according to comparative examples and examples.

FIG. 20 is a graph showing current characteristics in the thin film transistor according to FIGS. 19A and 19B.

FIG. 21 is a graph illustrating a change in threshold voltage (Vth) according to a change in an area of a conductive material layer.

FIG. 22 is a schematic diagram of a display apparatus according to an embodiment of the present disclosure.

FIG. 23 is a schematic diagram of a shift resist.

FIG. 24 is a circuit diagram of any one pixel of FIG. 22.

FIG. 25 is a plan view of the pixel of FIG. 24.

FIG. 26 is a cross-sectional view taken along line III-III′ of FIG. 25.

FIG. 27 is a circuit diagram of any one pixel of a display apparatus according to another embodiment of the present disclosure.

FIG. 28 is a circuit diagram of any one pixel of a display apparatus according to another embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle and a number disclosed in the drawings for describing embodiments of the present disclosure are merely an example and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or bencath” orientations.

In describing a temporal relationship, for example, when the temporal order is described as “after,” “subsequent,” “next,” and “before,” a case which is not continuous may be included, unless “just” or “direct” is used.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

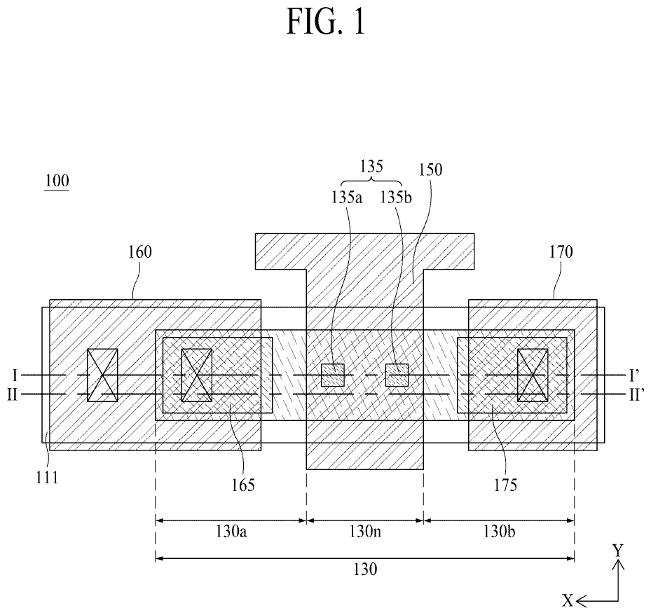

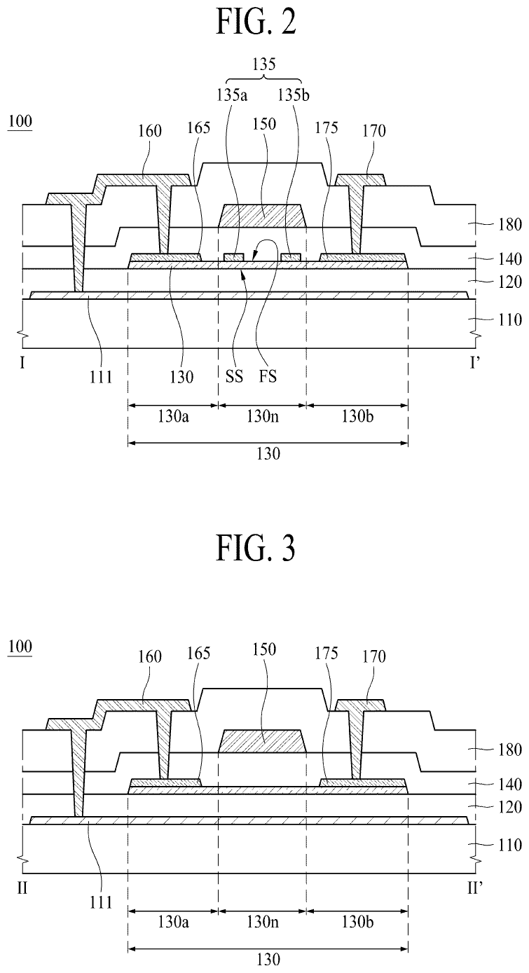

FIG. 1 is a plan view of a thin film transistor 100 according to an embodiment of the present disclosure. FIG. 2 is a cross-sectional view taken along line I-I′ of FIG. 1. FIG. 3 is a cross-sectional view taken along line II-II′ of FIG. 1.

Referring to FIGS. 1, 2, and 3, a thin film transistor 100 according to an embodiment of the present disclosure may include an active layer 130, a gate electrode 150, sub-conductive material layers 165 and 175, and a conductive material layer 135.

Specifically, referring to FIGS. 1, 2, and 3, a gate electrode 150 spaced apart from the active layer 130 and partially overlapping the active layer, sub-conductive material layer 165 and 175 on the active layer 130, and conductive material layer 135 on the active layer 130 may be included.

According to an embodiment of the present disclosure, the thin film transistor 100 may further include a base substrate 110. Referring to FIGS. 2 and 3, the active layer 130 is disposed on the base substrate 110.

The thin film transistor 100 according to an embodiment of the present disclosure may further include a buffer layer 120. Referring to FIGS. 2 and 3, the active layer 130 is disposed on the buffer layer 120. Specifically, the buffer layer 120 is disposed between the base substrate 110 and the active layer 130.

According to an embodiment of the present disclosure, the thin film transistor 100 may further include a gate insulating layer 140. Referring to FIGS. 2 and 3, the gate insulating layer 140 is disposed on the active layer 130. Specifically, the gate insulating layer 140 is disposed between the active layer 130 and the gate electrode 150.

According to an embodiment of the present disclosure, the thin film transistor 100 may further include an interlayer insulating layer 180. Referring to FIGS. 2 and 3, the interlayer insulating layer 180 is disposed on the gate electrode 150. Specifically, the gate electrode 150 is disposed between the gate insulating layer 140 and the interlayer insulating layer 180.

According to an embodiment of the present disclosure, the thin film transistor 100 may further include a source electrode 160 and a drain electrode 170. Referring to FIGS. 1, 2, and 3, the source electrode 160 and the drain electrode 170 are disposed on the interlayer insulating layer 180.

Hereinafter, components of the thin film transistor 100 according to an embodiment of the present disclosure will be described in more detail.

Glass or plastic may be used as the base substrate 110. A transparent plastic having flexible characteristics as plastic, for example, polyimide, may be used.

When polyimide is used as the base substrate 110, considering that a high-temperature deposition process is performed on the base substrate 110, heat-resistant polyimide capable of withstanding high-temperature may be used. In this case, in order to form a thin film transistor, processes such as deposition, etching, and the like may be performed in a state in which a polyimide substrate is disposed on a carrier substrate made of a highly durable material such as glass.

Referring to FIGS. 2 and 3, a buffer layer 120 may be disposed on the base substrate 110.

The buffer layer 120 may be formed on the base substrate 110 and may be formed of an inorganic material or an organic material. For example, insulating oxides such as silicon oxide (SiOx), aluminum oxide (Al2O3) and the like may be included.

The buffer layer 120 blocks impurities such as moisture and oxygen flowing from the base substrate 110 to protect the active layer 130, planarize the upper portion of the base substrate 110, and may be formed as a single layer or a plurality of layers.

Referring to FIGS. 2 and 3, the active layer 130 may be disposed on the buffer layer 120.

The active layer 130 may include a channel portion 130n, a first connection portion 130a, and a second connection portion 130b.

Specifically, the active layer 130 may include a channel portion 130n partially overlapping the gate electrode 150 in a plan view, a first connection portion 130a connected to one side of the channel portion 130n without overlapping the gate electrode 150 in a plan view, and a second connection portion 130b connected to the other side of the channel portion 130n without overlapping the gate electrode 150 in a plan view.

According to an embodiment of the present disclosure, the first connection portion 130a and the second connection portion 130b are spaced apart from each other with the channel portion 130n interposed therebetween.

According to an configuration of the present disclosure, the active layer 130 may be formed of a semiconductor material. The active layer 130 may include an oxide semiconductor material.

The oxide semiconductor material may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FelnZnO)-based oxide semiconductor material. However, an embodiment of the present disclosure is not limited thereto, and the active layer 130 may be made of another oxide semiconductor material known in the art.

The first connection portion 130a and the second connection portion 130b may be formed by selective conductorization with respect to the active layer 130 made of a semiconductor material. According to an embodiment of the present disclosure, imparting conductivity to a specific portion of the active layer 130 so that the same may function as a conductor is called selective conductorization.

For example, the active layer 130 may be selectively conductorized by ion doping. As a result, the first connection portion 130a and the second connection portion 130b may be formed. However, an embodiment of the present disclosure is not limited thereto, and the active layer 130 may be selectively conductorized by other methods known in the art.

The first connection portion 130a and the second connection portion 130b do not overlap the gate electrode 150. The first connection portion 130a and the second connection portion 130b have excellent electrical conductivity and high mobility compared to the channel portion 130n. Accordingly, the first connection portion 130a and the second connection portion 130b may function as a wiring, respectively.

According to an embodiment of the present disclosure, the thin film transistor 100 may include sub-conductive material layers 165 and 175 on the active layer 130.

Specifically, referring to FIGS. 1, 2 and 3, the sub-conductive material layers 165 and 175 may include a source conductive material layer 165 on the first connection portion 130a and a drain conductive material layer 175 on the second connection portion 130b.

More specifically, the source conductive material layer 165 and the drain conductive material layer 175 are disposed to be spaced apart from each other with a part of the channel portion 130n interposed therebetween.

Referring to FIGS. 1, 2, and 3, the first connection portion 130a and the second connection portion 130b may be disposed between the base substrate 110 and the source conductive material layer 165 and the drain conductive material layer 175, respectively.

More specifically, the source conductive material layer 165 and the drain conductive material layer 175 may contact the active layer 130 through the first connection portion 130a and the second connection portion 130b, respectively.

According to an embodiment of the present disclosure, the source conductive material layer 165 is disposed on the first connection portion 130a, and the drain conductive material layer 175 is disposed on the second connection portion 130b. However, an embodiment of the present disclosure is not limited thereto, and positions of the source conductive material layer 165 and the drain conductive material layer 175 may be exchanged with each other.

According to an embodiment of the present disclosure, each of the source conductive material layer 165 and the drain conductive material layer 175 may overlap portions of the first connection portion 130a and the second connection portion 130b. In FIGS. 1, 2, and 3, a configuration in which the source conductive material layer 165 overlaps a portion of the first connection portion 130a and the drain conductive material layer 175 overlaps a portion of the second connection portion 130b is illustrated.

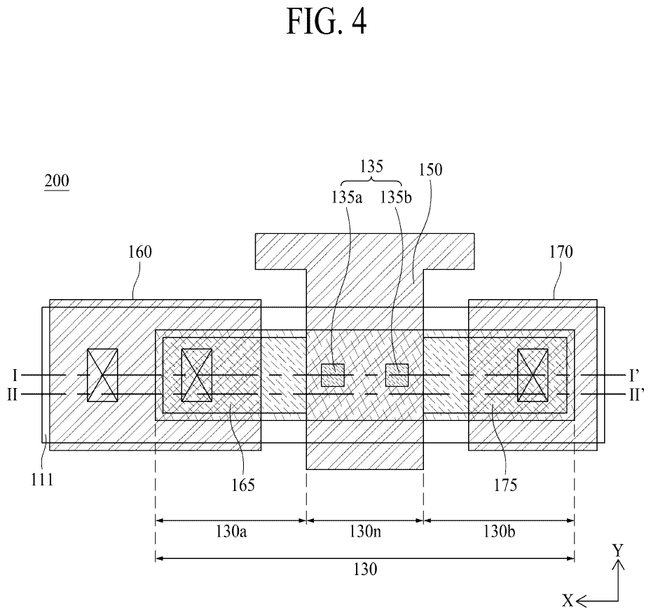

However, an embodiment of the present disclosure is not limited thereto, and each of the source conductive material layer 165 and the drain conductive material layer 175 may be disposed on the entire surfaces of the first connection portion 130a and the second connection portion 130b. FIGS. 4, 5, and 6 illustrate a configuration in which the source conductive material layer 165 is disposed on the entire surface of the first connection portion 130a, and the drain conductive material layer 175 is disposed on the entire surface of the second connection portion 130b. Also, although not shown in the drawings, a part of the sub-conductive material layers 165 and 175 may overlap the gate electrode 150.

According to an embodiment of the present disclosure, the sub-conductive material layer 165 and 175 may include at least one selected from metal and transparent conductive oxide (TCO).

Specifically, the metal may include at least one selected from titanium (Ti), molybdenum (Mo), aluminum (Al), silver (Ag), copper (Cu), chromium (Cr), tantalum (Ta), neodium (Nd), calcium (Ca), and barium (Ba). An embodiment of the present disclosure is not limited thereto, and the sub-conductive material layer 165 and 175 may include a metal having conductive properties.

According to an embodiment of the present disclosure, the transparent conductive oxide (TCO) may include ITO (InSnO), IZO (InZnO), IO (InO), TO (SnO), and ZO (ZnO). However, an embodiment of the present disclosure is not limited thereto, and the sub-conductive material layers 165 and 175 may include an oxide having conductivity.

The sub-conductive material layers 165 and 175 may have reducibility. The active layer 130 may be selectively conductorized by the sub-conductive material layers 165 and 175. According to an embodiment of the present disclosure, the first connection portion 130a and the second connection portion 130b are in contact with the source conductive material layer 165 and the drain conductive material layer 175, respectively. A region of the active layer 130 contacting the source conductive material layer 165 and the drain conductive material layer 175 is conductive to form a first connection portion 130a and a second connection portion 130b, respectively.

Specifically, according to an embodiment of the present disclosure, parts of the active layer 130 contacting the sub-conductive material layers 165 and 175 may be reduced, respectively, to form a first connection portion 130a and a second connection portion 130b.

For example, when a part of the active layer 130 contacting and overlapping the sub-conductive material layers 165 and 175 is reduced, oxygen vacancies occur in the active layer 130, and accordingly, the active layer 130 may be selectively conductorized. By selective reduction of the active layer 130, the first connection portion 130a and the second connection portion 130b may be formed.

According to an embodiment of the present disclosure, the thin film transistor 100 may further include a conductive material layer 135 on the active layer 130.

Specifically, referring to FIGS. 1, 2 and 3, the conductive material layer 135 may be disposed on the channel portion 130n of the active layer 130. More specifically, the conductive material layer 135 is not disposed on the first connection portion 130a and the second connection portion 130b of the active layer 130.

Referring to FIGS. 1, 2, and 3, the conductive material layer 135 may be disposed on the same layer as the sub-conductive material layers 165 and 175. The conductive material layer 135 and the sub-conductive material layers 165 and 175 are disposed between the active layer 130 and the gate insulating layer 140.

According to an embodiment of the present disclosure, the conductive material layer 135 may have one or more patterns. Specifically, the conductive material layer 135 may have a plurality of patterns or a single pattern. In FIGS. 1, 2, and 3, a configuration in which the conductive material layer 135 is a plurality of patterns is illustrated.

Referring to FIG. 2, the active layer 130 has a first surface FS and a second surface SS opposite the first surface FS. The second surface SS of the active layer 130 faces the substrate 110. The second surface SS of the active layer 130 is on and directly contacts the buffer layer 120. In some embodiments, the first conductive material layer 135a is on the first surface FS of the active layer 130. The second conductive material layer 135b is also on the first surface FS of the active layer 130 and is adjacent to and spaced apart from the first conductive material layer 135a. Further, a first sub-conductive material layer 165 is adjacent to and spaced apart from a second sub-conductive material layer 175. Here, the first sub-conductive material layer 165 is on the first surface FS of the active layer 130 and overlaps the first connection portion 130a from a plan view. Similarly, the second sub-conductive material layer 175 is on the first surface FS of the active layer 130 and overlaps the second connection portion 130b from a plan view.

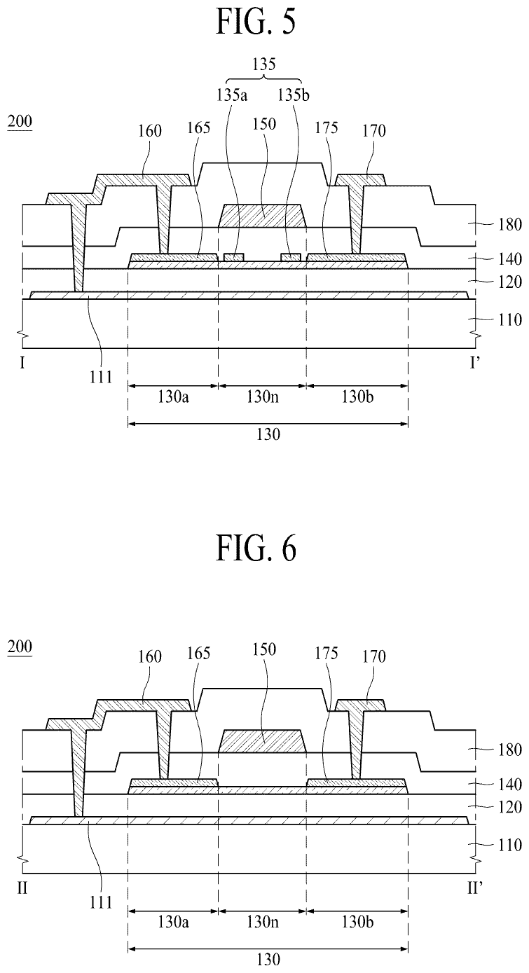

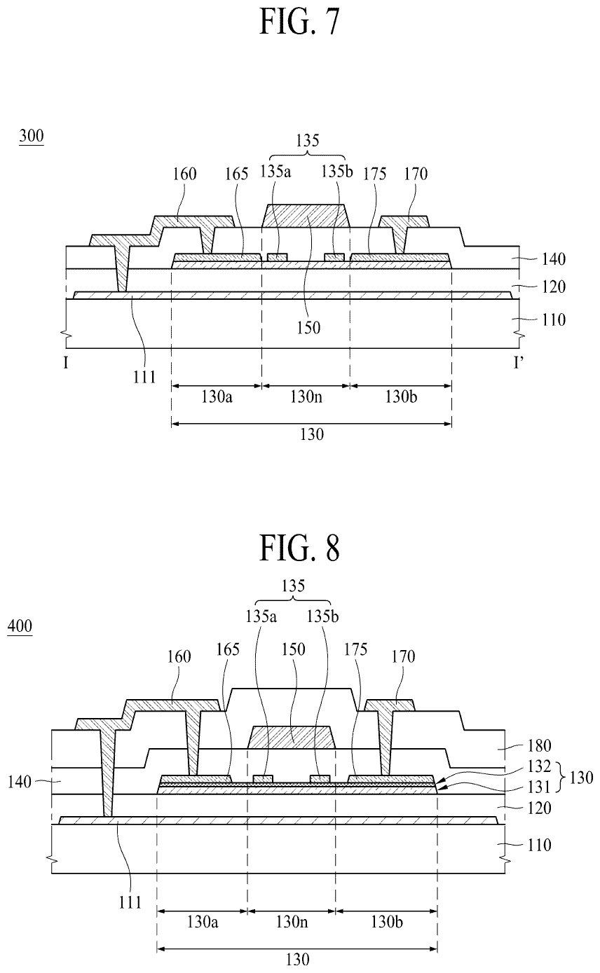

As shown in FIG. 5, in some embodiments, the first sub-conductive material layer 165 extends towards the first conductive material layer 135a and the second sub-conductive material 175 layer extends towards the second conductive material layer 135b. In these embodiments, the first sub-conductive material layer is not spaced apart from the gate electrode 150 from a plan view. Similarly, the second sub-conductive material layer 175 is not spaced apart from the gate electrode 150 from a plan view. In other words, when seen from a plan view as shown in FIG. 4, the end of the first sub-conductive material layer 165 contacts the gate electrode 150 without any gap from a plan view, and the end of the second sub-conductive material layer 175 contacts the gate electrode 150 without any gap from a plan view. Here, however, the end of the first sub-conductive material layer 165 does not reach the first conductive material layer 135a and therefore are spaced apart from each other. Similarly, the end of the second sub-conductive material layer 175 does not reach the second conductive material layer 135b and therefore are spaced apart from each other.

According to an embodiment of the present disclosure, an area of the conductive material layer 135 in the channel portion 130n may be 5 to 40% with respect to the entire area of the channel portion 130n when viewed in a plan view. As a result, the threshold voltage Vth of the thin film transistor according to the present disclosure may not be excessively shifted in the negative (−) direction and may have excellent on-current characteristics.

On the other hand, when the area of the conductive material layer 135 in the channel portion 130n is less than 5% with respect to the entire area of the channel portion 130n in a plan view, the conductive material layer 135 may be disposed in an excessively small amount in the channel portion 130n. As a result, an ON current characteristic of the thin film transistor according to the present disclosure may not be effectively improved.

Furthermore, when the area of the conductive material layer 135 in the channel portion 130n exceeds 40% with respect to the entire area of the channel portion 130n in a plan view, the conductive material layer 135 may be excessively disposed in the channel portion 130n. As a result, the threshold voltage Vth of the thin film transistor may be excessively shifted in the negative (−) direction.

In order to improve the ON current characteristics while the threshold voltage Vth of the thin film transistor according to the present disclosure is not excessively shifted in the negative (−) direction, the area of the conductive material layer 135 in the channel portion 130n needs to be adjusted to 5 to 40% based on the entire area of the channel portion 130n. Preferably, the area of the conductive material layer 135 in the channel portion 130n may be adjusted to 10 to 35%, more preferably 15 to 30%, based on the entire area of the channel portion 130n.

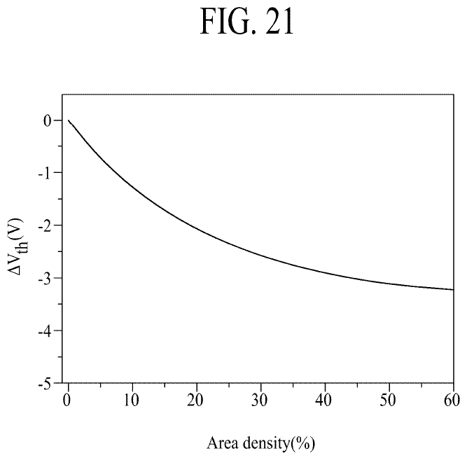

FIG. 21 is a graph illustrating a change in threshold voltage (Vth) according to a change in an area of a conductive material layer.

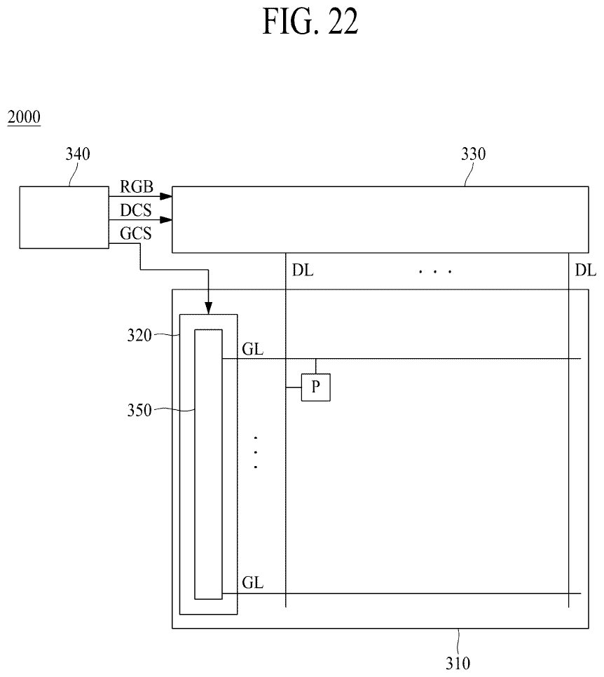

In the graph of FIG. 21, the horizontal axis represents a ratio of an area of the conductive material layer 135 with respect to the entire area of the channel portion 130n, and the vertical axis represents a threshold voltage (Vth) of the thin film transistor. As shown in the graph of FIG. 22, when the threshold voltage (Vth) moves in the negative (−) direction, the threshold voltage (Vth) is shifted in the negative (−) direction.

Referring to FIG. 21, it may be seen that the threshold voltage Vth gradually shifts in the negative (−) direction as the ratio of the area of the conductive material layer 135 increases with respect to the entire area of the channel portion 130n.

Referring to FIG. 21, when the part of the conductive material layer 135 is 5 to 40% based on the total part of the channel portion 130n, the threshold voltage Vth is not excessively shifted in the negative (−) direction, and at the same time, it can be seen that the current characteristics are improved.

On the other hand, when the area of the conductive material layer 135 is less than 5% based on the total area of the channel portion 130n, the threshold voltage Vth is prevented from being excessively shifted in the negative (−) direction, but does not have excellent on-current characteristics.

In addition, when the area of the conductive material layer 135 exceeds 40% based on the total area of the channel portion 130n, the threshold voltage Vth may be seen to be excessively shifted in the negative (−) direction.

According to an embodiment of the present disclosure, the conductive material layer 135 may include a first conductive material layer 135a and a second conductive material layer 135b. Specifically, the conductive material layer 135 may include a first conductive material layer 135a and a second conductive material layer 135b spaced apart from each other. More specifically, a configuration in which the first conductive material layer 135a and the second conductive material layer 135b are spaced apart from each other is shown in FIG. 1 and FIG. 2.

Referring to FIGS. 1 and 2, the first conductive material layer 135a is disposed closer to the first connection portion 130a than the second conductive material layer 135b. Also, the second conductive material layer 135b may be disposed closer to the second connection portion 130b than the first conductive material layer 135a. As a result, current characteristics of the thin film transistor according to the present disclosure may be improved.

More specifically, the first conductive material layer 135a may be disposed in a region of the channel portion 130n in contact with the first connection portion 130a, and the second conductive material layer 135b may be disposed in a region of the channel portion 130n in contact with the second connection portion 130b.

According to an embodiment of the present disclosure, the first conductive material layer 135a and the second conductive material layer 135b may be disposed on any shortest line connecting the first connection portion 130a and the second connection portion 130b in a plan view. In FIG. 1, an arbitrary shortest line LN connecting the first connection portion 130a and the second connection portion 130b is illustrated, and a configuration in which the first conductive material layer 135a and the second conductive material layer 135b are disposed on an arbitrary shortest line LN connecting the first connection portion 130a and the second connection portion 130b is illustrated. However, an embodiment of the present disclosure is not limited thereto, and the first conductive material layer 135a and the second conductive material layer 135b may not be disposed on any shortest line LN connecting the first connection portion 130a and the second connection portion 130b.

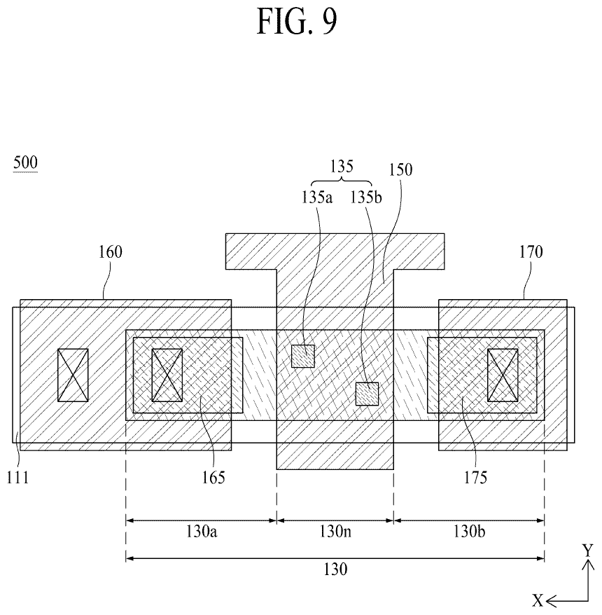

Specifically, referring to FIG. 9, a configuration in which the first conductive material layer 135a and the second conductive material layer 135b are not disposed on an arbitrary shortest line (not shown) connecting the first connection portion 130a and the second connection portion 130b. Even in this case, the first conductive material layer 135a may be disposed closer to the first connection portion 130a than the second conductive material layer 135b.

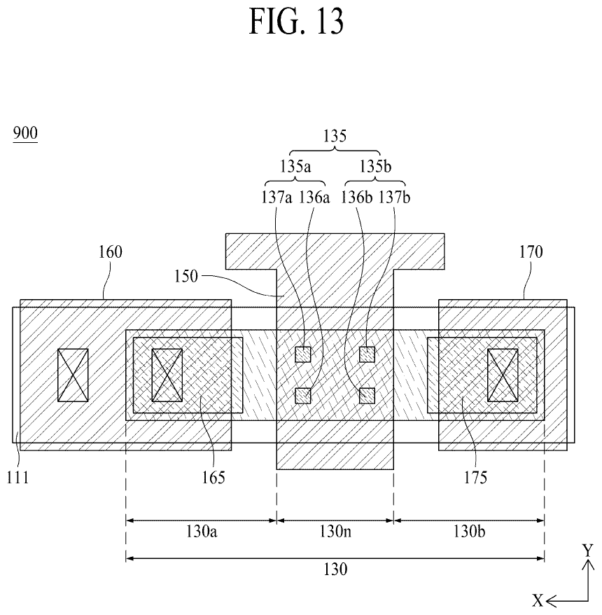

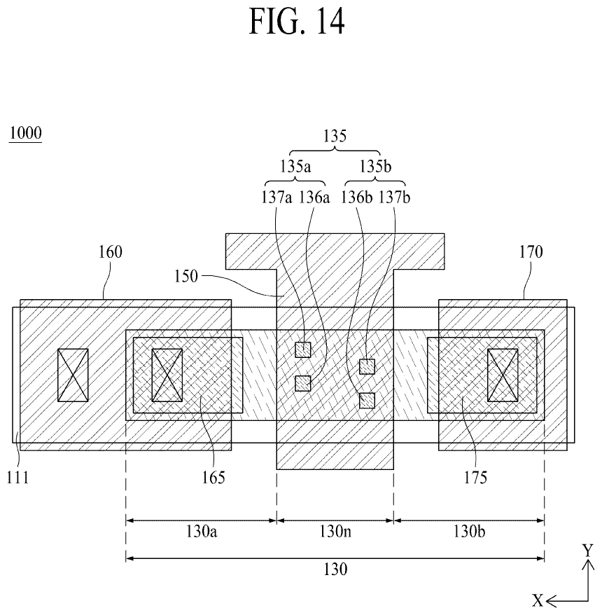

According to an embodiment of the present disclosure, each of the first conductive material layer 135a and the second conductive material layer 135b may have a plurality of patterns. Specifically, the first conductive material layer 135a may include a first sub-conductive material layer 136a and a second sub-conductive material layer 137a spaced apart from each other. Also, the second conductive material layer 135b may include a first sub-conductive material layer 136b and a second sub-conductive material layer 137b spaced apart from each other. In FIGS. 13 and 14, a first sub-conductive material layer 136a and a second sub-conductive material layer 137a disposed closer to the first connection portion 130a are illustrated, and a first sub-conductive material layer 136b and a second sub-conductive material layer 137b disposed closer to the second connection portion 130b are illustrated.

Referring to FIG. 13, the first sub-conductive material layer 136a of the first conductive material layer 135a and the first sub-conductive material layer 136b of the second conductive material layer 135b may be disposed on an arbitrary shortest line (not illustrated) connecting the first connection portion 130a and the second connection portion 130b.

Compared with FIG. 13, FIG. 14 shows that the first sub-conductive material layer 136a and the second sub-conductive material layer 137a of the first conductive material layer 135a and the first sub-conductive material layer 136b and the second sub-conductive material layer 137b of the second conductive material layer 135b may not be disposed on any shortest line (not illustrated) connecting the first connection portion 130a and the second connection portion 130b, respectively.

An embodiment of the present disclosure is not limited to the positions of the first sub-conductive material layers 136a and 136b and the second sub-conductive material layers 137a and 137b illustrated in FIGS. 13 and 14, and the positions of the first sub-conductive material layers 136a and 136b and the second sub-conductive material layers 137a and 137b may be changed. Also, the first conductive material layer 135a and the second conductive material layer 135b may include a third sub-conductive material layer (not shown), and may include more.

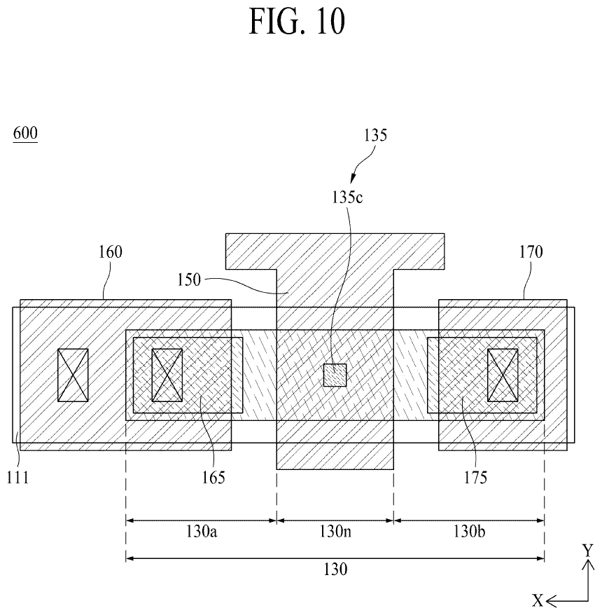

According to an embodiment of the present disclosure, the conductive material layer 135 may include a third conductive material layer 135c disposed at the same distance from the first connection portion 130a and the second connection portion 130b, respectively, when viewed in a plan view. FIG. 10 shows the third conductive material layer 135c disposed at the same distance from the first connection portion 130a and the second connection portion 130b, respectively.

Specifically, the third conductive material layer 135c may be disposed at a boundary part of a region of the channel portion 130n in contact with the first connection portion 130a and a region of the channel portion 130n in contact with the second connection portion 130b.

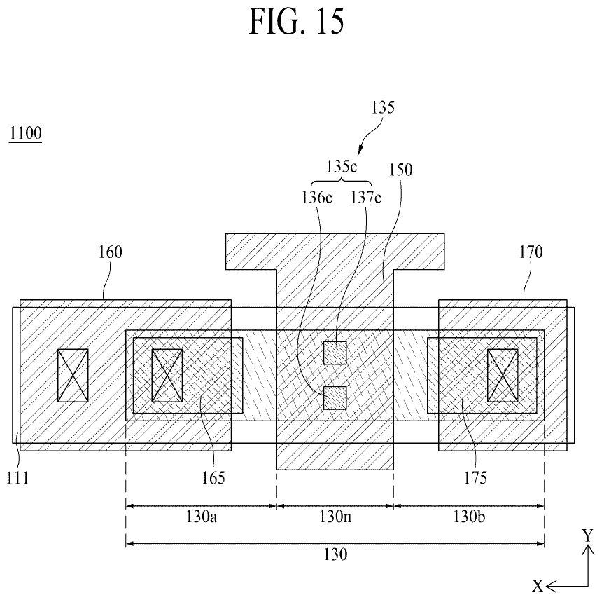

According to an embodiment of the present disclosure, the third conductive material layer 135c may have a plurality of patterns. Specifically, the third conductive material layer 135c may include a first sub-conductive material layer 136c and a second sub-conductive material layer 137c spaced apart from each other. FIG. 15 illustrates a first sub-conductive material layer 136c and a second sub-conductive material layer 137c disposed at the same distance as the first connection portion 130a and the second connection portion 130b, respectively.

An embodiment of the present disclosure is not limited to the positions of the first sub-conductive material layer 136c and the second sub-conductive material layer 137c shown in FIG. 15, and the positions of the first sub-conductive material layer 136c and the second sub-conductive material layer 137c may be changed. Also, the third conductive material layer 135c may include a third sub-conductive material layer (not shown), and may include more.

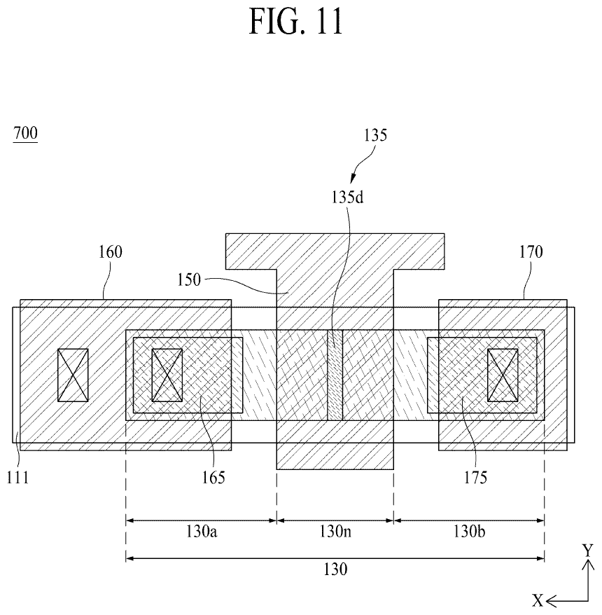

According to an embodiment of the present disclosure, when a channel length direction of the active layer 130 is a first direction X and a width direction of the active layer 130 is a second direction Y, the conductive material layer 135 may include a fourth conductive material layer 135d having a length in the second direction Y longer than a length in the first direction X. Specifically, FIG. 11 illustrates a fourth conductive material layer 135d having a length in the second direction Y longer than a length in the first direction X.

More specifically, the fourth conductive material layer 135d may be disposed in parallel with the second direction Y.

According to an embodiment of the present disclosure, both ends of the fourth conductive material layer 135d may contact both ends of the channel portion 130n based on the second direction Y. FIG. 11 illustrates a configuration in which both ends of the fourth conductive material layer 135d are in contact with both ends of the channel portion 130n based on the second direction Y.

However, the embodiment of this disclosure is not limited to it, and both ends of the fourth conductive material layer (135d) may not contact both ends of the channel portion (130n) based on the second direction (Y).

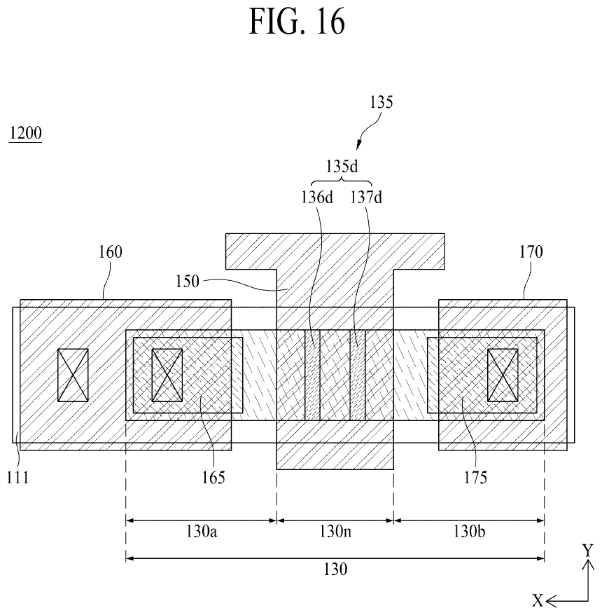

According to an embodiment of the present disclosure, the fourth conductive material layer 135d may have a plurality of patterns. Specifically, the fourth conductive material layer 135d may include a first sub-conductive material layer 136d and a second sub-conductive material layer 137d, which are spaced apart from each other. FIG. 16 illustrates the first sub-conductive material layer 136d and the second sub-conductive material layer 137d, whose length in the second direction Y is greater than a length in the first direction X.

An embodiment of the present disclosure is not limited to the positions of the first sub-conductive material layer 136d and the second sub-conductive material layer 137d shown in FIG. 16, and the positions of the first sub-conductive material layer 136d and the second sub-conductive material layer 137d may be changed. Also, the fourth conductive material layer 135d may include a third sub-conductive material layer (not shown), and may include more.

In addition, FIG. 16 shows a configuration in which the ends of the first sub-conductive material layer 136d and the second sub-conductive material layer 137d contact both ends of the channel portion 130n based on the second direction Y, but is not limited thereto, and either end of the first sub-conductive material layer 136d or the second sub-conductive material layer 137d may contact both ends of the channel portion 130n, and the ends of the first sub-conductive material layer 136d and the second sub-conductive material layer 137d may not contact both ends of the channel portion 130n.

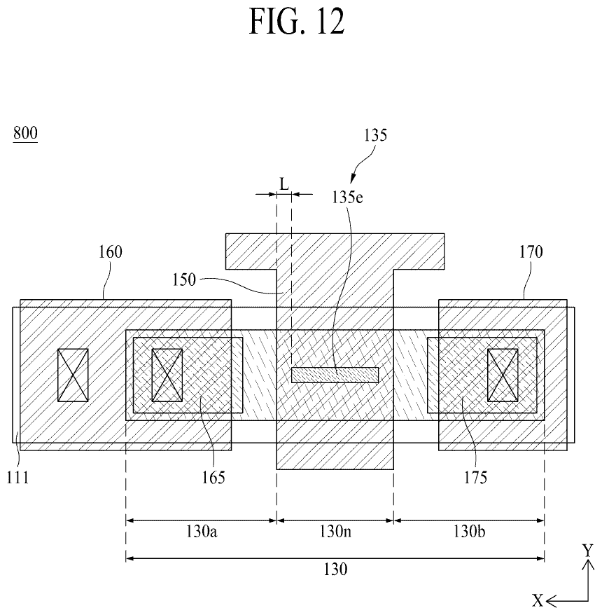

According to an embodiment of the present disclosure, when a channel length direction of the active layer 130 is a first direction X and a width direction of the active layer 130 is a second direction Y, the conductive material layer 135 may include a fifth conductive material layer 135e having a length in the first direction X longer than a length in the second direction Y. Specifically, FIG. 12 illustrates a fifth conductive material layer 135e having a length in the first direction X longer than a length in the second direction Y.

More specifically, the fifth conductive material layer 135e may be disposed parallel to the first direction X.

According to an embodiment of the present disclosure, the fifth conductive material layer 135e may be disposed in the channel portion 130n with respect to the first direction X. FIG. 12 illustrates the fifth conductive material layer 135e disposed in the channel portion 130n with respect to the first direction X.

More specifically, the fifth conductive material layer 135e is spaced apart from the first connection portion 130a and the second connection portion 130b.

According to an embodiment of the present disclosure, a distance between the fifth conductive material layer 135e, the first connection portion 130a, and the second connection portion 130b may be 1 μm or more based on the first direction X.

Specifically, referring to FIG. 12, when a distance between the fifth conductive material layer 135e and the first connection portion 130a and the second connection portion 130b is L, L may be 1 μm or more. As a result, the threshold voltage Vth of the thin film transistor according to the present disclosure is not excessively shifted in the negative (−) direction, and at the same time, current characteristics may be improved.

On the other hand, when the distance L between the fifth conductive material layer 135e, the first connection portion 130a, and the second connection portion 130b is less than 1 μm, the distance between the fifth conductive material layer 135e, the first connection portion 130a, and the second connection portion 130b becomes very close, and conduction to the channel portion 130n is excessively performed, such that the threshold voltage Vth of the thin film transistor may be excessively shifted in the negative (−) direction.

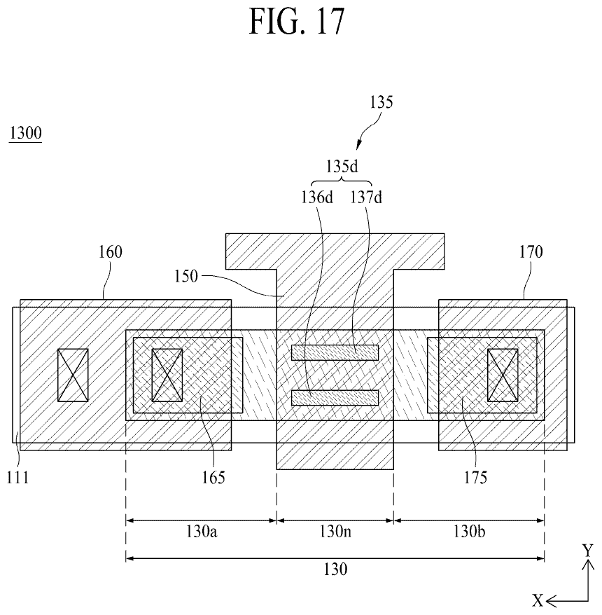

According to an embodiment of the present disclosure, the fifth conductive material layer 135c may have a plurality of patterns. Specifically, the fifth conductive material layer 135c may include a first sub-conductive material layer 136e and a second sub-conductive material layer 137e, which are spaced apart from each other. In FIG. 17, the first sub-conductive material layer 136e and the second sub-conductive material layer 137e are illustrated, respectively, in the first direction X. Each of the first sub-conductive material layer 136e and the second sub-conductive material layer 137e may be disposed in the channel portion 130n based on the first direction X.

An embodiment of the present disclosure is not limited to the positions of the first sub-conductive material layer 136e and the second sub-conductive material layer 137e shown in FIG. 17, and the positions of the first sub-conductive material layer 136e and the second sub-conductive material layer 137e may be changed. Also, the fifth conductive material layer 135e may include a third sub-conductive material layer (not shown), and may include more than that.

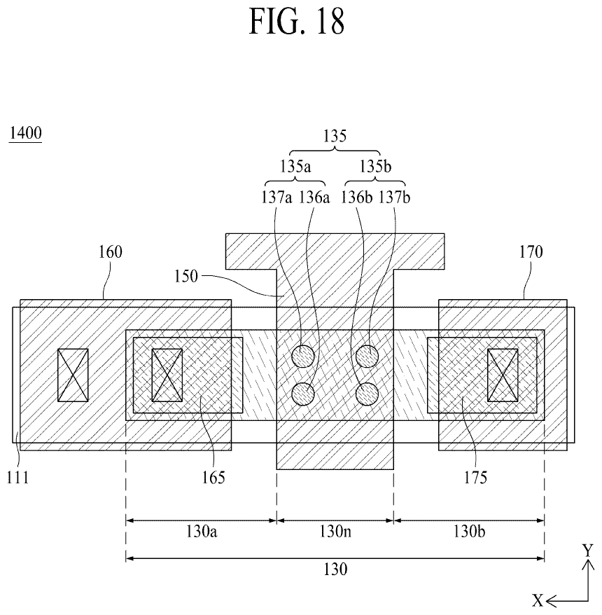

According to an embodiment of the present disclosure, the conductive material layer 135 may have a circular shape, an oval shape, a semicircular shape, a semi-ellipse shape, and a polygonal shape when seen from a plan view. FIG. 18 shows a configuration in which the conductive material layer 135 has a circular shape. However, an embodiment of the present disclosure is not limited thereto, and the conductive material layer 135 may have various planar shapes. For example, the conductive material layer 135 may have a circular shape, an oval shape, a semicircular shape, a semi-ellipse shape, and a polygonal plane, and may have a plane having an irregular shape.

FIG. 18 shows a configuration in which each of the first sub-conductive material layer 136a and 136b and the second sub-conductive material layer 137a and 137b has a circular shape. However, an embodiment of the present disclosure is not limited thereto, and any one of the first sub-conductive material layer 136a and 136b and the second sub-conductive material layer 137a and 137b may have a different shape.

According to an embodiment of the present disclosure, a region of the channel portion 130n overlapping the conductive material layer 135 may have a higher carrier concentration than a region not overlapping the conductive material layer 135.

According to an embodiment of the present disclosure, the sub-conductive material layers 165 and 175 may include at least one selected from titanium (Ti), molybdenum (Mo), aluminum (Al), silver (Ag), copper (Cu), chromium (Cr), tantalum (Ta), neodium (Nd), calcium (Ca), barium (Ba), and transparent conductive oxide (TCO), and the conductive material layer 135 may also be formed of the same material as the sub-conductive material layers 165 and 175. Therefore, the conductive material layer 135 may have reducibility.

Specifically, portions of the channel portion 130n, which are in contact with and overlap with the conductive material layer 135, may be reduced, respectively. For example, when a portion of the channel portion 130n, which contacts and overlaps the conductive material layer 135, is reduced, oxygen vacancies occur in the channel portion 130n, and thus the channel portion 130n may be selectively conductorized. Therefore, a region of the channel portion 130n, which overlaps the conductive material layer 135, may have a higher carrier concentration than a region not overlapping the conductive material layer 135, and as a result, current characteristics of the thin film transistor may be effectively improved.

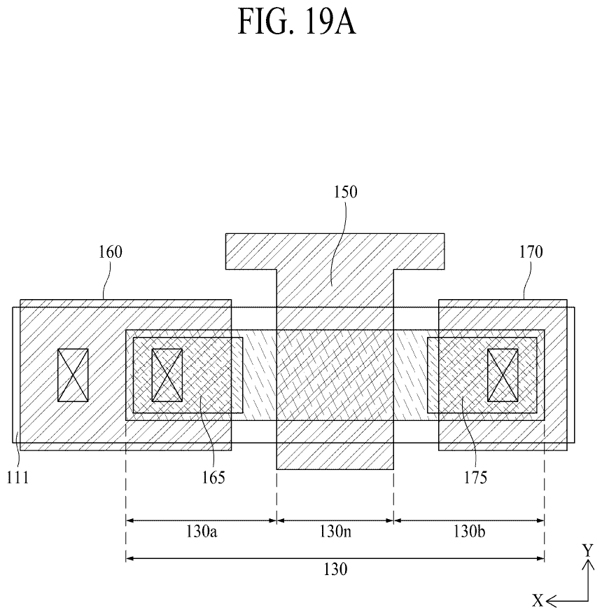

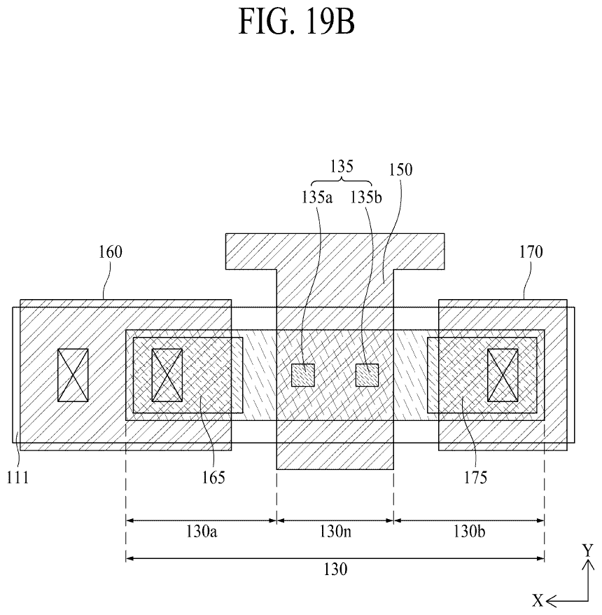

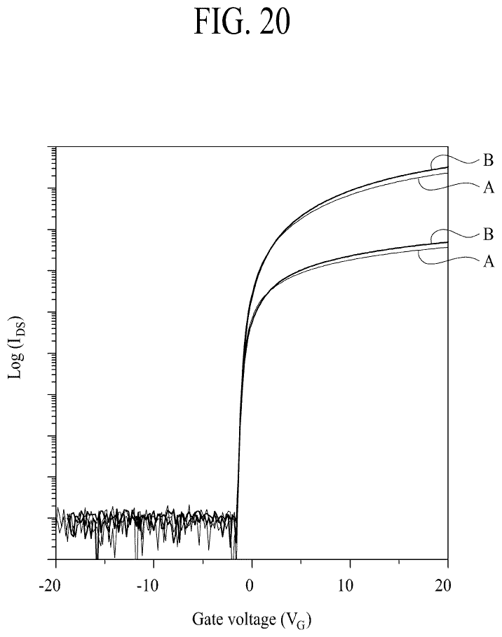

FIGS. 19A and 19B are plan views of thin film transistors according to comparative examples and examples, and FIG. 20 is a graph showing current characteristics in the thin film transistor according to FIGS. 19A and 19B.

In the graph of FIG. 20, a horizontal axis denotes a gate voltage VG, and a vertical axis denotes a log value of the drain-source current IDS. Also, FIG. 20A illustrates a current characteristic of the thin film transistor according to FIG. 19A, and FIG. 20B illustrates a current characteristic of the thin film transistor according to FIG. 19B.

FIG. 19A is a plan view of a thin film transistor according to a comparative example, in which the conductive material layer 135 is not disposed on the channel portion 130n. On the other hand, FIG. 19B is a plan view of a thin film transistor according to an embodiment, in which the conductive material layer 135 is disposed on the channel portion 130n. Specifically, although FIG. 19B shows the first conductive material layer 135a and the second conductive material layer 135b, an embodiment of the present disclosure is not limited thereto, and any one of the third conductive material layer 135c, the fourth conductive material layer 135d, and the fifth conductive material layer 135e may be disposed on the channel portion 130n.

In the case of an embodiment in which the conductive material layer 135 is disposed on the channel portion 130n (see FIG. 19B), a region of the channel portion 130n overlapping the conductive material layer 135 may be reduced by the conductive material layer 135 to selectively become a conductor. Accordingly, a region of the channel portion 130n overlapping the conductive material layer 135 may have a higher carrier concentration than a region not overlapping the conductive material layer 135, and as a result, current characteristics of the thin film transistor may be effectively improved. In this case, FIG. 20B shows current characteristics of the thin film transistor according to an embodiment.

On the other hand, in the case of the comparative example (see FIG. 19A) in which the conductive material layer 135 is not disposed on the channel portion 130n, the conductive material layer 135 is not disposed on the channel portion 130n, and thus a region to be selectively conductorized among the channel portions 130n does not exist, and thus the channel portion 130n has a lower carrier concentration than that of the comparative example, and as a result, current characteristics of the thin film transistor are not effectively improved. In this case, FIG. 20A shows current characteristics of the thin film transistor according to the comparative example.

According to an embodiment of the present disclosure, the active layer 130 of the thin film transistor 400 may have a multilayer structure. For example, the active layer 130 may include a first active layer 131 and a second active layer 132.

Specifically, referring to FIG. 8, the active layer 130 may include a first active layer 131 and a second active layer 132 on the first active layer 131.

The first active layer 131 and the second active layer 132 may include the same semiconductor material, or may include different semiconductor materials.

The first active layer 131 supports the second active layer 132. Accordingly, the first active layer 131 is also referred to as a “support layer”. The active layer 130 has a structure consisting of the first active layer 131 and the second active layer 132 and is also referred to as a bi-layer structure.

Although not illustrated in the drawing, the active layer 130 may further include a third active layer 133 on the second active layer 132, and the active layer 130 may further include another semiconductor layer.

According to an embodiment of the present disclosure, the thin film transistor may further include a gate insulating layer 140 between the active layer 130 and the gate electrode 150. Specifically, the gate insulating layer 140 may cover the entire upper surface of the active layer 130. FIG. 2 illustrates a configuration in which the gate insulating layer 140 covers the entire upper surface of the active layer 130.

However, an embodiment of the present disclosure is not limited thereto, and the first connection portion 130a and the second connection portion 130b of the active layer 130 may be exposed from the gate insulating layer 140.

The gate insulating layer 140 may include at least one of silicon oxide, silicon nitride, and metal oxide. The gate insulating layer 140 may have a single layer structure or a multilayer structure. The gate insulating layer 140 protects the channel portion 130n.

Referring to FIG. 2, a gate electrode 150 is disposed on the gate insulating layer 140. The gate electrode 150 overlaps the channel portion 130n of the active layer 130.

The gate electrode 150 may include at least one among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, and chromium (Cr), tantalum (Ta), neodium (Nd), and titanium (Ti). The gate electrode 150 may have a multilayer structure including at least two conductive layers having different physical properties.

Referring to FIG. 2, an interlayer insulating layer 180 is disposed on the gate electrode 150 and the gate insulating layer 140. The interlayer insulating layer 180 is an insulating layer made of an insulating material. The interlayer insulating layer 180 may be formed of an organic material, an inorganic material, or a laminate of an organic material layer and an inorganic material layer.

Referring to FIG. 2, a source electrode 160 and a drain electrode 170 are disposed on the interlayer insulating layer 180.

Although not illustrated in the drawings, the source electrode 160 and the drain electrode 170 may be disposed on the gate insulating layer 140 and may be disposed on the same layer as the gate electrode 150. The source electrode 160 and the drain electrode 170 may be made of the same material as the gate electrode 150 by the same process.

Each of the source electrode 160 and the drain electrode 170 may include at least one of aluminum-based metals such as aluminum (Al) or aluminum alloy, silver-based metals such as silver (Ag) or silver alloy, copper-based metals such as copper (Cu) or copper alloy, molybdenum-based metals such as molybdenum (Mo) or molybdenum alloy, chromium (Cr), tantalum (Ta), neodium (Nd), and titanium (Ti). The source electrode 160 and the drain electrode 170 may have a multilayer structure including at least two conductive films having different physical properties.

Referring to FIGS. 1 and 2, the source electrode 160 and the drain electrode 170 are connected to the active layer 130 through contact holes, respectively. Specifically, the source electrode 160 and the drain electrode 170 are connected to the active layer 130 by contacting the source conductive material layer 165 and the drain conductive material layer 175, respectively.

Referring to FIGS. 1, 2, and 3, the light blocking layer 111 may be disposed on the base substrate 110. Specifically, the light blocking layer 111 may be disposed between the base substrate 110 and the active layer 130. The light blocking layer 111 overlaps the channel portion 130n. The light blocking layer 111 blocks light incident from the outside, thereby protecting the channel portion 130n.

The light blocking layer 111 may be formed of a material having light blocking characteristics. The light blocking layer 111 may include at least one of an aluminum-based metal such as aluminum (Al) or an aluminum alloy, a molybdenum-based metal such as molybdenum (Mo) or a molybdenum alloy, chromium (Cr), tantalum (Ta), neodium (Nd), titanium (Ti), and iron (Fc). According to an embodiment of the present disclosure, the light blocking layer 111 may have electrical conductivity.

The light blocking layer 111 may be omitted. Although not illustrated in FIGS. 1, 2 and 3, a buffer layer may be additionally disposed between the base substrate 110 and the light blocking layer 111. The light blocking layer 111 may be electrically connected to one of the source electrode 160 and the drain electrode 170. FIG. 2 illustrates a configuration in which the light blocking layer 111 is electrically connected to the source electrode 160.

FIG. 22 is a schematic diagram illustrating a display apparatus 2000 according to further still another embodiment of the present disclosure.

As shown in FIG. 22, the display apparatus 2000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 2000 according to one embodiment of the present disclosure may include the above-described thin film transistors 100, 200, 300, 400, 500, 600, 700, 800, 900, 1000, 1100, 1200, 1300, and 1400. According to one embodiment of the present disclosure, the gate driver 320 may include the above-described thin film transistors 100, 200, 300, 400, 500, 600, 700, 800, 900, 1000, 1100, 1200, 1300, and 1400.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100, 200, 300, 400, 500, 600, 700, 800, 900, 1000, 1100, 1200, 1300, and 1400.

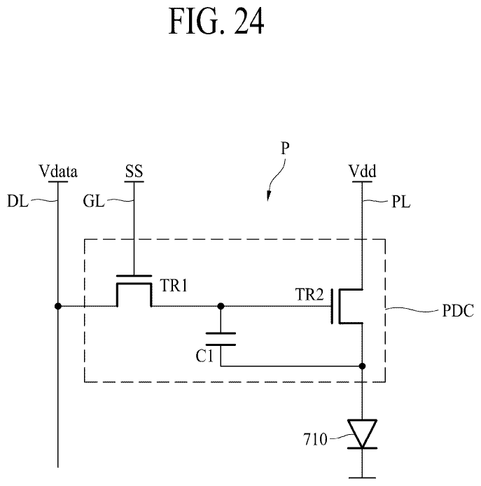

Referring to FIG. 22, the display panel 310 includes a plurality of pixels P and these pixels may include subpixels. Each pixel P may include a light emitting element such as a light emitting diode or an organic light emitting diode (OLED). The light emitting element may also be referred to as a display element 710. In addition, each pixel P may include a thin film transistor TFT coupled to the light emitting element 710. The thin film transistor coupled to the light emitting element 710 may be the second thin film transistor TR2 as shown in FIG. 24.

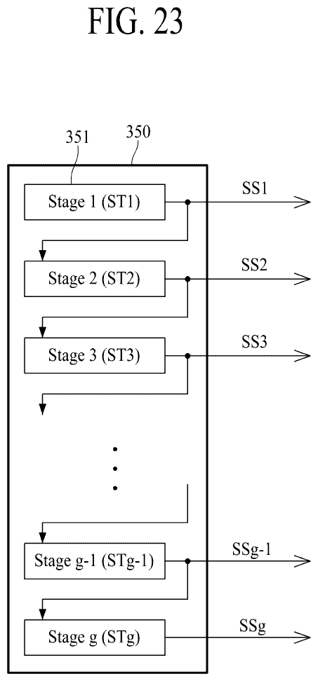

FIG. 23 is a schematic diagram illustrating a shift register 350.

Referring to FIG. 23, the shift register 350 may include g number of stages 351 (ST1 to STg).

The shift register 350 transmits one scan signal SS to pixels P connected to one gate line GL through one gate line GL. Each of the stages 351 may be connected to one gate line GL. When g number of gate lines GL are formed in the display panel 310, the shift register 350 may include g number of stages 351 (ST1 to STg), and may generate g number of scan signals SSI to SSg.

In general, each stage 351 outputs the gate pulse GP once during one frame, and the gate pulses GP are sequentially output from each stage 351.

FIG. 24 is a circuit view illustrating any one pixel P of FIG. 22.

The circuit view of FIG. 24 is an equivalent circuit view for the pixel P of the display apparatus 2000 that includes an organic light emitting diode (OLED) as a display element 710.

Referring to FIG. 24, the pixel P includes a display element 710 and a pixel driving circuit PDC for driving the display element 710. In detail, the display apparatus 2000 according to one embodiment of the present disclosure may include a pixel driving circuit PDC on the base substrate 110.

The pixel driving circuit PDC of FIG. 24 includes a first thin film transistor TR1 that is a switching transistor and a second thin film transistor TR2 that is a driving transistor. The display apparatus 2000 according to another embodiment of the present disclosure may include at least one of the above-described thin film transistors 100, 200, 300, 400, 500, 600, 700, 800, 900, 1000, 1100, 1200, 1300, and 1400.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

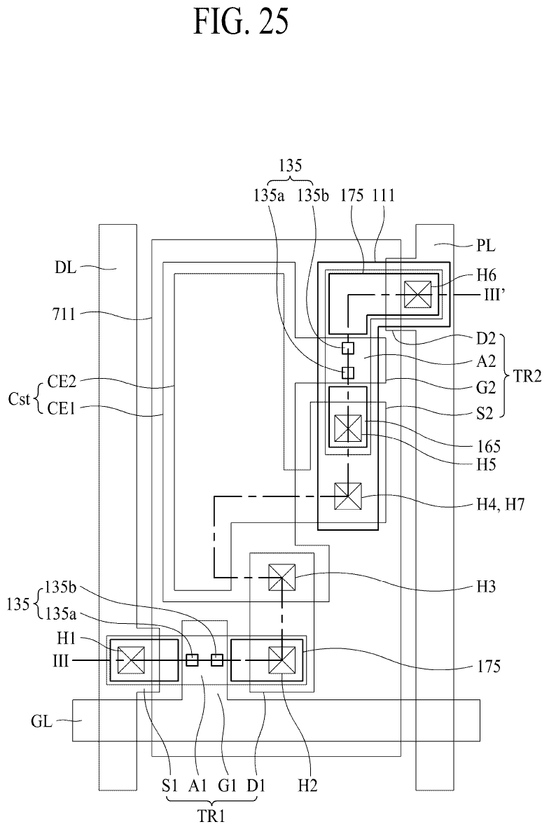

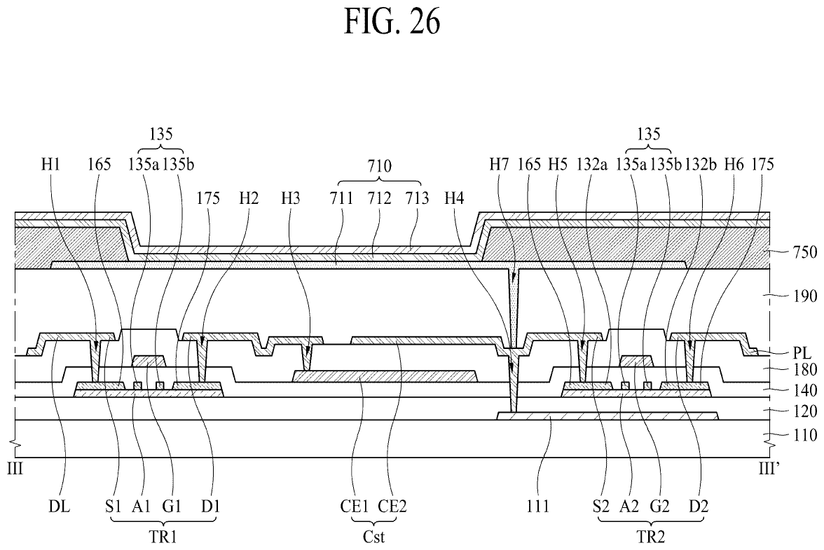

FIG. 25 is a plan view of the pixel of FIG. 24, and FIG. 26 is a cross-sectional view taken along line III-III′ of FIG. 25.

Referring to FIGS. 25 and 26, the first thin film transistor TR1 and the second thin film transistor TR2 are disposed on the base substrate 110.

The base substrate 110 may be made of glass or plastic. As the base substrate 110, plastic having flexible characteristics, for example, polyimide (PI), may be used.

The light blocking layer 111 is disposed on the base substrate 110. The light blocking layer 111 may have a light blocking characteristic. The light blocking layer 111 may block light incident from the outside to protect the active layers A1 and A2.

The buffer layer 120 is disposed on the light blocking layer 111. The buffer layer 120 is made of an insulating material and protects the active layers A1 and A2 from moisture or oxygen introduced from the outside.

An active layer A1 of the first thin film transistor TR1 and an active layer A2 of the second thin film transistor TR2 are disposed on the buffer layer 120.

The active layers A1 and A2 may include, for example, an oxide semiconductor material. The active layers A1 and A2 may have a multilayer structure made of an oxide semiconductor material.

Sub-conductive material layers 165 and 175 may be disposed on the active layers A1 and A2.

According to an embodiment of the present disclosure, the sub-conductive material layer 165 and 175 may include at least one selected from metal and transparent conductive oxide (TCO).

A conductive material layer 135 may be further included on the active layers A1 and A2. Specifically, the conductive material layer 135 may be disposed on the channel portion of the active layers A1 and A2.

The gate insulating layer 140 is disposed on the active layers A1 and A2. The gate insulating layer 140 covers upper surfaces of the active layers A1 and A2.

The gate electrode G1 of the first thin film transistor TR1 and the gate electrode G2 of the second thin film transistor TR2 are disposed on the gate insulating layer 140.

Although not shown in the drawings, a gate line GL may be disposed on the gate insulating layer 140. The gate electrode G1 of the first thin film transistor TR1 may extend from the gate line GL or may be a part of the gate line GL.

Referring to FIGS. 25 and 26, a first capacitor electrode CE1 of the storage capacitor Cst is formed on the gate insulating layer 140. The first capacitor electrode CE1 may be formed by the same material as the gate electrodes G1 and G2 by the same process.

An interlayer insulating layer 180 is disposed on the gate electrodes G1 and G2 and the first capacitor electrode CE1.

A data line DL and a driving power line PL are disposed on the interlayer insulating layer 180. Also, the source electrode S1 and the drain electrode D1 of the first thin film transistor TR1 are disposed on the interlayer insulating layer 180, and the source electrode S2 and the drain electrode D2 of the second thin film transistor TR2 are disposed on the interlayer insulating layer 180.

The source electrode S1 of the first thin film transistor TR1 may be integrally formed with the data line DL, and may have a structure extending from the data line DL.

The source electrode S1 of the first thin film transistor TR1 may be in contact with the side surface of the active layer A1 of the first thin film transistor TR1 through the first contact hole H1.

A drain electrode D1 of the first thin film transistor TR1 contacts another side surface of the active layer A1 of the first thin film transistor TR1 through a second contact hole H2. Also, a drain electrode D1 of the first thin film transistor TR1 is connected to the first capacitor electrode CE1 through a third contact hole H3. As a result, the first capacitor electrode CE1 may be connected to the first thin film transistor TR1.

The drain electrode D2 of the second thin film transistor TR2 may be integrally formed with the driving power line PL, and may have a structure extending from the driving power line PL.

The drain electrode D2 of the second thin film transistor TR2 may be in contact with the side surface of the active layer A2 of the second thin film transistor TR2 through the sixth contact hole H6.

The source electrode S2 of the second thin film transistor TR2 is in contact with the other side surface of the active layer A2 of the second thin film transistor TR2 through the fifth contact hole H5. Also, the source electrode S2 of the second thin film transistor TR2 is connected to the light blocking layer 111 through the fourth contact hole H4. The same voltage as the source electrode S2 of the second thin film transistor TR2 may be applied to the light blocking layer 111 overlapping the second thin film transistor TR2.

The source electrode S2 of the second thin film transistor TR2 may extend onto the interlayer insulating layer 145 to form the second capacitor electrode CE2 of the storage capacitor Cst.

According to an embodiment of the present disclosure, the first capacitor electrode CE1 and the second capacitor electrode CE2 may overlap to form a storage capacitor Cst.

Referring to FIGS. 25 and 26, a planarization layer 190 is disposed on the data line DL, the driving power line PL, the source electrodes S1 and S2, the drain electrodes D1 and D2, and the second capacitor electrode CE2. The planarization layer 190 planarizes upper portions of the first thin film transistor TR1 and the second thin film transistor TR2, and protects the first thin film transistor TR1 and the second thin film transistor TR2. The planarization layer 190 serves as a protective layer.

A first electrode 711 of the display element 710 is disposed on the planarization layer 190. The first electrode 711 of the display element 710 is in contact with the second capacitor electrode CE2 through a seventh contact hole H7 formed in the planarization layer 190. As a result, the first electrode 711 of the display element 710 may be connected to the source electrode S2 of the second thin film transistor TR2.

A bank layer 750 is disposed at an edge of the first electrode 711. The bank layer 750 defines a light emitting area of the display element 710.

The organic light emitting layer 712 is disposed on the first electrode 711, and the second electrode 713 is disposed on the organic light emitting layer 712. Accordingly, the display element 710 is completed. The display element 710 illustrated in FIG. 26 is an organic light emitting diode (OLED). Therefore, the display apparatus 2000 according to an embodiment of the present disclosure is an organic light emitting display apparatus.

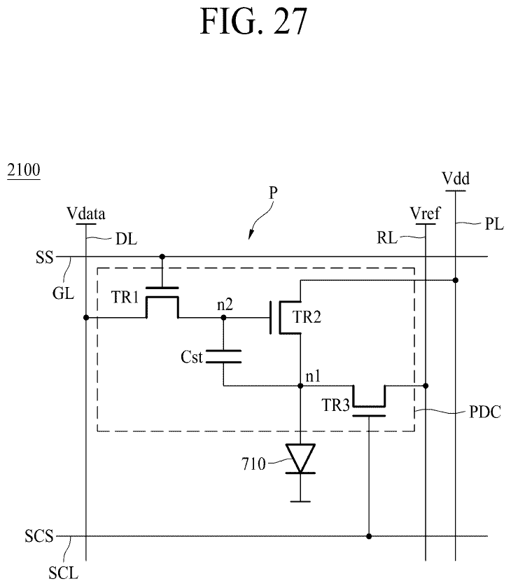

FIG. 27 is a circuit diagram of any one pixel of a display apparatus 2100 according to another embodiment of the present disclosure.

FIG. 27 is an equivalent circuit diagram of a pixel P of an organic light emitting display apparatus.

The pixel P of the display apparatus 2100 shown in FIG. 27 includes an organic light emitting diode OLED, which is a display element 710, and a pixel driving circuit PDC for driving the display element 710. The display element 710 is connected to the pixel driving circuit PDC.

Signal lines DL, GL, PL, RL, and SCL for supplying signals to the pixel driving circuit PDC are arranged in the pixel P.

The data voltage Vdata is supplied to the data line DL, the scan signal SS is supplied to the gate line GL, the driving voltage Vdd for driving the pixel is supplied to the driving power line PL, the reference voltage Vref is supplied to the reference line RL, and the sensing control signal SCS is supplied to the sensing control line SCL.

The pixel driving circuit PDC includes, for example, the first thin film transistor TR1 (switching transistor) connected to the gate line GL and the data line DL, the second thin film transistor TR2 (driving transistor) that controls the magnitude of the current output to the display element 710 according to the data voltage Vdata transmitted through the first thin film transistor TR1, and the third thin film transistor TR3 (sensing transistor) for sensing the characteristics of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2.

The third thin film transistor TR3 is connected to the first node n1 and the reference line RL between the second thin film transistor TR2 and the display element 710, is turned on or off by the sensing control signal SCS, and detects characteristics of the second thin film transistor TR2, which is a driving transistor during the sensing period.

A second node n2 connected to the gate electrode of the second thin film transistor TR2 is connected to the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2.

When the second thin film transistor TR2 is turned on, current is supplied to the display element 710 through the second thin film transistor TR2 by the driving voltage Vdd driving the pixel, and light is output from the display element 710.

The display apparatus 2100 according to another embodiment of the present disclosure may include at least one of the thin film transistors 100, 200, 300, 400, 500, 600, 700, 800, 900, 1000, 1100, 1200, 1300, and 1400.

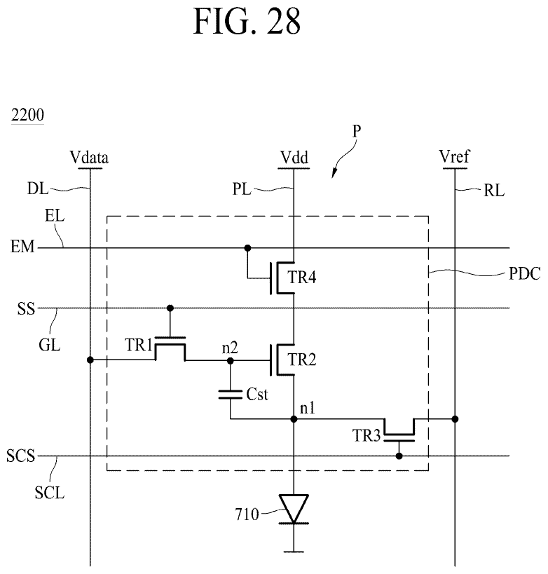

FIG. 28 is a circuit diagram of any one pixel P of a display apparatus 2200 according to another embodiment of the present disclosure.

The pixel P of the display apparatus 2200 shown in FIG. 28 includes an organic light emitting diode OLED, which is a display element 710, and a pixel driving circuit PDC for driving the display element 710. The display element 710 is connected to the pixel driving circuit PDC.

The pixel driving circuit PDC includes thin film transistors TR1, TR2, TR3, and TR4.

Signal lines DL, EL, GL, PL, SCL, and RL that supply driving signals to the pixel driving circuit PDC are arranged in the pixel P.

Compared with the pixel P of FIG. 27, the pixel P of FIG. 28 further includes an emission control line EL. The emission control signal EM is supplied to the emission control line EL. Also, compared with the pixel driving circuit PDC of FIG. 27, the pixel driving circuit PDC of FIG. 28 further includes a fourth thin film transistor TR4, which is an emission control transistor for controlling an emission time point of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2.

A storage capacitor Cst is positioned between the gate electrode of the second thin film transistor TR2 and the display element 710.

The third thin film transistor TR3 is connected to the reference line RL, is turned on or off by the sensing control signal SCS, and detects characteristics of the third thin film transistor TR3, which is a driving transistor, during the sensing period.

The fourth thin film transistor TR4 transfers the driving voltage Vdd to the second thin film transistor TR2 or blocks the driving voltage Vdd according to the emission control signal EM. When the fourth thin film transistor TR4 is turned on, a current is supplied to the second thin film transistor TR2 to output light from the display element 710.

The pixel driving circuit PDC according to another exemplary configuration of the present disclosure may be formed in various structures other than the structure described above. The pixel driving circuit PDC may include, for example, five or more thin film transistors.

According to the present disclosure, the following advantageous effects may be obtained.

The thin film transistor according to an embodiment of the present disclosure may include a conductive material layer disposed on a channel portion, thereby improving current characteristics.

The thin film transistor according to an embodiment of the present disclosure includes a conductive material layer disposed on the channel portion, and the threshold voltage Vth is not excessively shifted in the negative (−) direction and current characteristics may be improved.

The thin film transistor according to an embodiment of the present disclosure includes a conductive material layer disposed on a channel portion, and can maintain current characteristics even if the channel portion has a small width.

In addition to the above-mentioned effects, other features and advantages of the present disclosure will be described below or clearly understood by those of ordinary skill in the art to which the present disclosure belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer on a base substrate;
a sub-conductive material layer on the active layer;
a gate electrode spaced apart from the active layer and at least partially overlapping the active layer; and
a conductive material layer on the active layer;
the active layer includes:
a channel portion partially overlapping the gate electrode;
a first connection portion coupled to one side of the channel portion; and
a second connection portion coupled to the other side of the channel portion;
the sub-conductive material layer includes:
a source conductive material layer on the first connection portion; and
a drain conductive material layer on the second connection portion;
the conductive material layer is disposed on the channel portion and is disposed on a same layer as the sub-conductive material layer.

2. The thin film transistor of claim 1, an area of the conductive material layer in the channel portion is 5% to 40% based on a total area of the channel portion, in a plan view.

3. The thin film transistor of claim 1, each of the source conductive material layer and the drain conductive material layer overlap portions of the first connection portion and the second connection portion.

4. The thin film transistor of claim 3, each of the source conductive material layer and the drain conductive material layer is disposed on the entire surfaces of the first connection portion and the second connection portion.

5. The thin film transistor of claim 1, wherein the conductive material layer includes a first conductive material layer and a second conductive material layer spaced apart from each other.

6. The thin film transistor of claim 5, wherein the first conductive material layer is disposed closer to the first connection portion than the second conductive material layer.

7. The thin film transistor of claim 5, wherein the first conductive material layer and the second conductive material layer is disposed on an arbitrary shortest line connecting the first connection portion and the second connection portion in a plan view.

8. The thin film transistor of claim 5, wherein the first conductive material layer and the second conductive material layer is not disposed on an arbitrary shortest line connecting the first connection portion and the second connection portion in a plan view.

9. The thin film transistor of claim 5, wherein the first conductive material layer includes a first sub-conductive material layer and a second sub-conductive material layer spaced apart from each other, and
wherein the second conductive material layer includes a first sub-conductive material layer and a second sub-conductive material layer spaced apart from each other.

10. The thin film transistor of claim 1, wherein the conductive material layer includes a third conductive material layer disposed on a same distance as each of the first connection portion and the second connection portion in a plan view.

11. The thin film transistor of claim 1, when a channel length direction of the active layer is a first direction and a width direction of the active layer is a second direction, the conductive material layer includes a fourth conductive material layer having a length in the second direction longer than a length in the first direction.

12. The thin film transistor of claim 11, based on the second direction, both ends of the fourth conductive material layer contact both ends of the channel portion.

13. The thin film transistor of claim 1, when a channel length direction of the active layer is a first direction and the width direction of the active layer is a second direction, the conductive material layer includes a fifth conductive material layer having a length in the first direction longer than a length in the second direction.

14. The thin film transistor of claim 13, wherein the fifth conductive material layer is disposed in the channel portion based on the first direction.

15. The thin film transistor of claim 14, each distance between the fifth conductive material layer and the first connection portion and the second connection portion is 1 μm or more based on the first direction.

16. The thin film transistor of claim 1, a region of the channel portion overlapping the conductive material layer have a higher carrier concentration than a region not overlapping the conductive material layer.

17. The thin film transistor of claim 1, wherein the sub-conductive material layer includes at least one selected from metal and transparent conductive oxide (TCO).

18. The thin film transistor of claim 1, wherein the conductive material layer is formed of a same material as the sub-conductive material layer.

19. The thin film transistor of claim 1, wherein the active layer includes at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

20. A display apparatus comprising;
a display panel including a light emitting element and a thin film transistor coupled to the light emitting element, the thin film transistor including:
a substrate;
an active layer on the substrate, the active layer including a first connection portion, a second connection portion, and a channel portion between the first connection portion and the second connection portion, the active layer having a first surface and a second surface opposite the first surface, the second surface facing the substrate;
a conductive material layer on the first surface of the active layer;
a gate electrode spaced apart from the conductive material layer; and
a source electrode and a drain electrode adjacent to the gate electrode;
wherein the channel portion overlaps the gate electrode from a plan view;
wherein the conductive material layer includes a first conductive material layer that overlaps with the gate electrode from a plan view.

21. The display apparatus of claim 20, comprising;
a second conductive material layer adjacent to and spaced apart from the first conductive material layer,
wherein the second conductive material layer overlaps with the gate electrode from a plan view.

22. The display apparatus of claim 20, comprising;
a first sub-conductive material layer adjacent to and spaced apart from a second sub-conductive material layer,
wherein the first sub-conductive material layer is on the first surface of the active layer and overlaps the first connection portion from a plan view,
wherein the second sub-conductive material layer is on the first surface of the active layer and overlaps the second connection portion from a plan view.

23. The display apparatus of claim 22, wherein the first sub-conductive material layer extends towards the first conductive material layer and the second sub-conductive material layer extends towards the first conductive material layer,
wherein either the first sub-conductive material layer or the second sub-conductive material layer is not spaced apart from the gate electrode from a plan view.

24. The display apparatus of claim 21, comprising:
a first sub-conductive material layer adjacent to and spaced apart from a second sub-conductive material layer,
wherein the first sub-conductive material layer is on the first surface of the active layer and overlaps the first connection portion from a plan view,
wherein the second sub-conductive material layer is on the first surface of the active layer and overlaps the second connection portion from a plan view,
wherein the first sub-conductive material layer extends towards the first conductive material layer and the second sub-conductive material layer extends towards the second conductive material layer,
wherein either the first sub-conductive material layer or the second sub-conductive material layer is not spaced apart from the gate electrode from a plan view, and
wherein the first conductive material and the first sub-conductive material are spaced apart from each other.

25. The display apparatus of claim 20, comprising:
a first sub-conductive material layer adjacent to and spaced apart from a second sub-conductive material layer,
wherein the active layer includes a first active layer and a second active layer on the first active layer
wherein the first sub-conductive material layer is on the second active layer and overlaps the first connection portion from a plan view, and
wherein the second sub-conductive material layer is on second active layer and overlaps the second connection portion from a plan view.

26. The display apparatus of claim 25, wherein the first sub-conductive material layer and the second sub-conductive material layer extend towards the first conductive material layer,
wherein either the first sub-conductive material layer or the second sub-conductive material layer is not spaced apart from the gate electrode from a plan view.

27. The display apparatus of claim 25, wherein the first sub-conductive material layer and the second sub-conductive material layer extend towards the first conductive material layer,
wherein either the first sub-conductive material layer or the second sub-conductive material layer is spaced apart from the gate electrode from a plan view.

28. The display apparatus of claim 20, wherein the first conductive material layer has a rectangular shape, a square shape, a polygonal shape, or a semicircular shape or a circular shape from a plan view.
